(19) United States
(12) Patent Application Publication
(10) Pub. No.: US 2024/0411229 A1
(43) Pub. Date: Dec. 12, 2024

(54) HIGH RESOLUTION PHOTOLITHOGRAPHY

(71) Applicant: TERA-PRINT LLC, Skokie, IL (US)

(72) Inventors: Andrey IVANKIN, Northbrook, IL (US); Jared A. MAGOLINE, Lebanon, IN (US); William O. HUTSON, Evanston, IL (US); Jeremy T. LUTZ, Chicago, IL (US)

(21) Appl. No.: 18/736,307

(22) Filed: Jun. 6, 2024

Related U.S. Application Data
(60) Provisional application No. 63/471,336, filed on Jun. 6, 2023.

(51) Int. Cl. G03F 7/00; G03F 7/20

(52) U.S. Cl. CPC G03F 7/70291; G03F 7/2041; G03F 7/70116; G03F 7/70258; G03F 7/70358; G03F 7/70516; G03F 7/70525; G03F 7/70716; G03F 7/70858; G03F 7/70991

(57) ABSTRACT

Devices, systems, and method for high resolution photolithography can include a mounting stage for receiving a substrate in position to receive projected light for photolithography, a light processing system for projecting light onto the mounting stage for photolithography on the substrate, and a positioning system for adjusting relative positioning between the light processing system and the mounting stage. A control system for conducting operations for high resolution photolithography, can be configured to determine relative positioning between the light processing system and the mounting stage and for governing operation of the positioning system for adjusting relative positioning.

### CROSS-REFERENCE

This utility application claims the benefit of priority to U.S. Provisional Application No. 63/471,336, filed on Jun. 6, 2023, entitled “HIGH RESOLUTION PHOTOLITHOGRAPHY” the contents of which are hereby incorporated by reference in their entirety.

### FIELD

The present disclosure concerns devices, systems, and methods for photolithography. More specifically, the present disclosure concerns devices, systems, and methods for high resolution photolithography.

### SUMMARY

According to an aspect of the present disclosure, a high resolution photolithography system may comprise a mounting stage for receiving a substrate in position to receive projected light for photolithography; a light processing system for projecting light onto the mounting stage for photolithography on the substrate; a positioning system for adjusting relative positioning between the light processing system and the mounting stage; and a control system for conducting operations for high resolution photolithography. The control system may be configured to determine relative positioning between the light processing system and the mounting stage and for governing operation of the positioning system for adjusting relative positioning.

In some embodiments, the light processing system may include at least one digital light projector (DLP) comprising a Digital Micromirror Device (DMD) chipset comprising a plurality of micromirrors. The control system may be configured to calibrate the DLP for illumination intensity by defining a correction profile corresponding to a duty cycle for each of the plurality of micromirrors. The control system may be configured to define the correction profile by setting the duty cycle at 100% for one of the micromirrors having the lowest native intensity as a reference micromirror. The control system may be configured for determining the duty cycle for other ones of the micromirrors by comparison to the reference micromirror.

In some embodiments, the control system may be configured to support illumination uniformity of within about ±5% of average illumination over at least 95% of an illumination area of the DLP. The control system may encode the determined duty cycle for each of micromirrors directly onto the DMD chipset. The control system may be configured to define a plurality of grayscale images from a native image. The control system may be configured to govern projection of the grayscale images in series from the light processing system onto the mounting stage to build up image-by-image printing of the native image on the substrate.

In some embodiments, the control system may be configured for conducting autofocusing by governing projection of a predetermined pattern from the light processing system onto the mounting stage for projection on the substrate, capturing an image of the pattern on the substrate having projection thereon, and decomposing the captured image of the pattern into spatial-frequency amplitude. The control system may be configured to govern adjustment of a focal plane of the DLP based on the spatial-frequency amplitude of the captured image. Configuration to govern adjustment of the focal plane may include configuration to govern at least one of adjusting a Z-position of the light projection system relative to the mounting stage, coordinating camera exposure of the substrate by time of light propagation, and maximizing contrast at edges of the predetermined pattern.

In some embodiments, the control system may be configured for conducting tip-tilt adjustment including governing the positioning system for the light processing system relative to the mounting stage to address at least two different portions of the substrate and to adjust a Z-position of the light projection system relative to the mounting stage for each of the at least two different portions of the substrate for autofocusing. The at least two different portions may include at least two different perimeter portions of the substrate. Conducting tilt-tilt adjustment may include governing the positioning system for tip-tilt including rotation of the mounting stage about at least one of X, Y, and Z axes.

In some embodiments, the high resolution photolithography system may further comprise a sample environmental control feedback system for precisely modulating the temperature and humidity of the environment for patterning the substrate. In some embodiments, the system may further comprise a sample environment control system for introduction of one or more fluids for patterning the substrate. The sample environment control system may include a sealed chamber received by the mounting stage for receiving the substrate and a fluidics system for selective introduction of the one or more fluids into the sealed chamber for patterning the substrate.

In some embodiments, the fluidics system may include a number of fluid reservoirs and a fluidic flow control system for controlling injection of the one or more fluids into the sealed chamber. The fluidic control system may include one or more fluidic chip modules for processing fluids before injection into the sealed chamber. The control system may be configured to govern operation of the one or more fluidic chip modules for multi-step printing. At least one of the one or more fluidic chip modules may be a microfluidic chip module. In some embodiments, the fluidics system may include a mixing chamber for mixing two of more fluids according to governing by the control system.

According to another aspect of the present disclosure, a method of high resolution photolithography may include defining one or more images for printing via a light processing system onto at least one sample substrate; aligning the light processing system with the at least one sample substrate received on a mounting stage, wherein aligning includes determining, via a control system, relative positioning between the light processing system and the mounting stage and governing operation of the positioning system for adjusting relative positioning; and printing the one or more images by projecting light onto the substrate from the light processing system.

In some embodiments, aligning may include autofocusing. Autofocusing may be by projection of a predetermined pattern from the light processing system onto the mounting stage for projection on the sample substrate, capture of an image of the pattern on the substrate having projection thereon, decomposition the captured image of the pattern into spatial-frequency amplitude, and adjustment of a focal plane of a DLP of the light processing system, via the control system, based on the spatial-frequency amplitude of the captured image.

In some embodiments, aligning may include tip-tilt adjustment. Tip-tilt adjustment may comprise addressing at least two different portions of the sample substrate and adjusting a Z-position of the light projection system relative to the mounting stage with respect to each of the at least two different portions of the substrate for autofocusing. The at least two different portions include at least two different perimeter portions of the substrate.

In some embodiments, printing may include injecting one or more fluids into a sealed chamber of the mounting stage, via a fluidics system. Printing may include printing high-resolution, wide-area, high-fidelity DNA microarrays onto arbitrarily sized glass substrates, via injection of fluids into the sealed fluidic chamber in coordination with DLP projection. Printing may be conducted subsequent to tip-tilt adjustment and auto-focusing.

In some embodiments, printing may include microfabricating microfluidics devices, other fluidics devices, sensors, wearable electronic devices, microelectronics, microlenses, metamaterials, microrobotics, microarray fabrication via photopatterning and/or in-situ photosynthesis, and/or tissue engineering. In some embodiments, compatible materials include but are not limited to commercial photoresists, hydrogels, biomolecules, polymers, and/or any other suitable photoresponsive materials.

### BRIEF DESCRIPTION

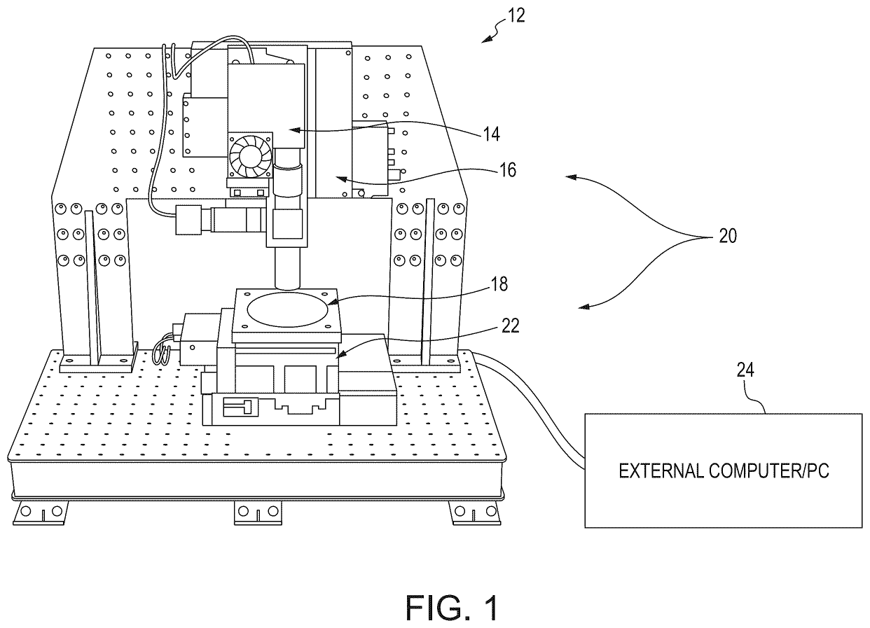

FIG. 1 (Schematic 1) is a perspective view of a high resolution photolithography system;

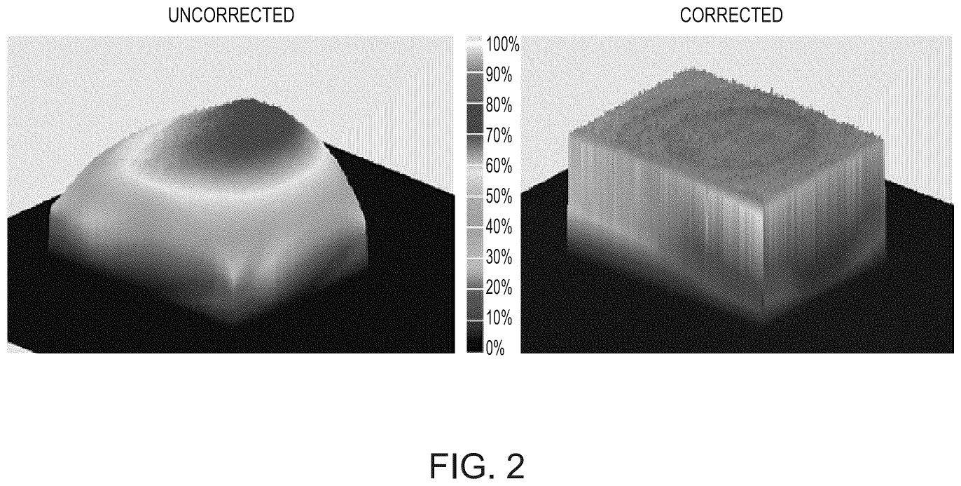

FIG. 2 (Schematic 2) is a chart representing light intensity profile of the high resolution photolithography system of FIG. 1 showing an uncorrected profile (left) and corrected profile (right);

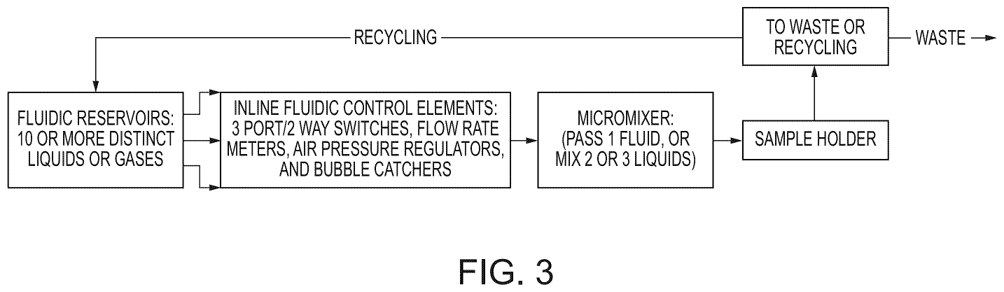

FIG. 3 (Schematic 3) is flow diagram concerning fluidics of the high resolution photolithography system of FIGS. 1 & 2;

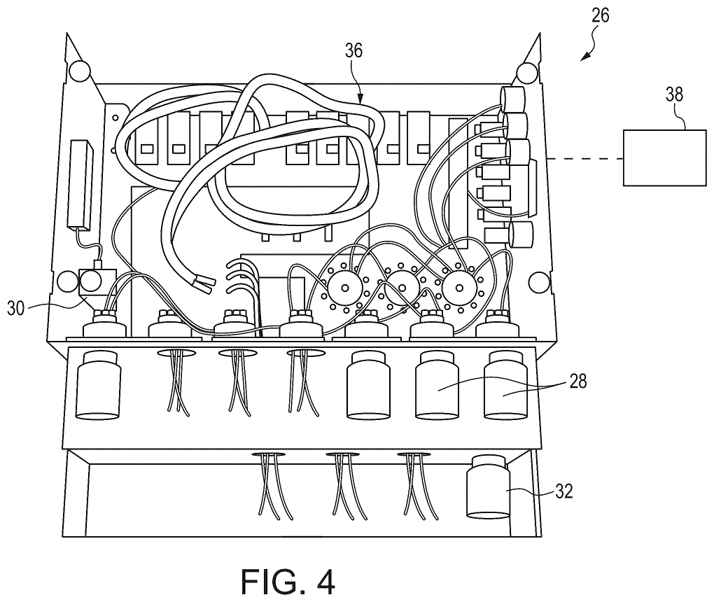

FIG. 4 is an elevation view of a fluidics system for providing precision control of fluids introduced to a sample/substrate of interest addressed by the a high resolution photolithography system of FIG. 1; and

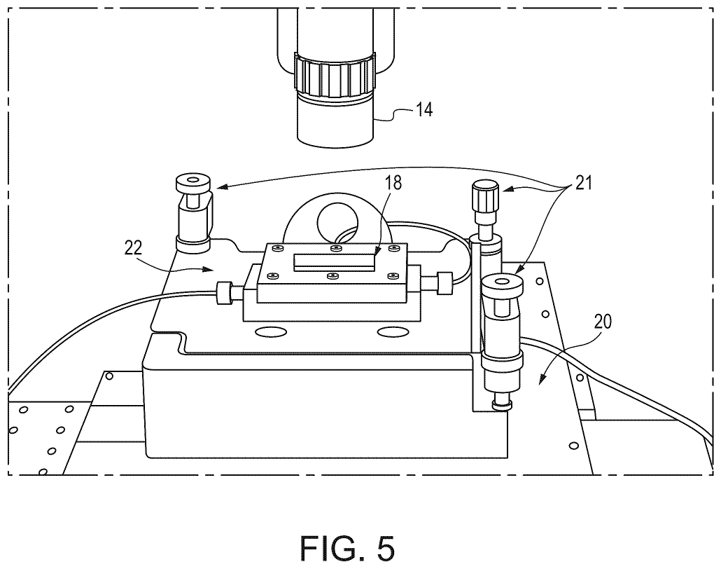

FIG. 5 is a close perspective view of a mounting stage of the a high resolution photolithography system of FIG. 1.

### DETAILED DESCRIPTION

Within the present disclosure, devices, systems, and methods of high resolution photolithography are discussed. For example, maskless photolithography tools can enable the patterning of photoresponsive materials on a variety of surfaces, over large areas, and with high resolution. Referring to FIG. 1, the high resolution photolithography system 12 comprises a light processing system 14 illustratively embodied as a digital light processing unit (DLP) (forming a UV-projector) mounted to a Z-axis motorized stage 16 for light focusing. A mounting stage 18 illustratively defining a sample holder is illustratively oriented below the DLP (which can include either a substrate chuck (e.g., vacuum chuck) or custom fluid exchange cell) mounted to a positioning system 20 illustratively including high-resolution XY platform (stages) 22 for addressing the sample area and the Z-axis motor stage 16. The system illustratively includes a tip/tilt stage integrated into the sample area assembly to allow adjustment of samples for parallelism with projected light. The system illustratively includes a rotation stage to allow adjustment of samples for orthogonality with the light projection and/or for in-registry printing. The system includes a control system 24 configured for overall operation via processor instructions, which may be embodied as integrated or external computer processor and auxiliaries.

In the illustrative embodiment, the system includes the digital light processing unit (DLP) that can provide high illumination uniformity. For example, high illumination uniformity can include power within over 95% of the illumination area is standardized to be within about ±5% of the average. The system illustratively includes selectable objective lenses according to the particular application, and multi-light source (e.g., LEDs, lasers, fiber optics, etc.) illumination. In the illustrative embodiment, the multi-light source is a dual-LED source, but in some embodiments may include any suitable number and/or manner of light source. The DLP illustratively includes a DMD chipset (e.g., 0.95″, 1920×1080 pixels, or equivalent alternative). The DMD chipset illustratively includes a custom projection lens assembly that can achieve high contrast and/or highly uniform image quality over the full projection area. The high resolution photolithography system also utilize custom optics, for example, including light homogenization rod, RTIR prism, to enhance the brightness and/or uniformity of projection, and/or TIR or RTIR prism used to illuminate the DMD and relay the image into the projection optics.

The DLP is calibrated with a correction profile to enable maximum illumination uniformity for each DLP. The calibration with correction profile is illustratively conducted by capturing the native light intensity profile from the DMD at the DLP focus, for example, with a beam profiler. The power delivered can be determined at the focus for each individual DMD mirror. The captured native light intensity profile can be normalized programmatically by adjusting each individual mirror's duty cycle. For example, for a given period, each DMD mirror can be directed to spend a certain percentage of that time in its ‘ON’ state, sending light down the optical path toward the sample, vs. its ‘OFF’ state, where its light is rejected from propagating down the optical path toward the sample.

By setting the DMD mirror (pixel) with the lowest native intensity (PX1) with a duty cycle of 100% (i.e., this pixel is set to be in its ‘ON’ state 100% of the time). All other pixels can be ‘tuned’ to produce the same intensity as PX1 by decreasing their duty cycle in proportion to their native power vs. the power of PX1 as suggested in FIG. 2. A pixel size of 10.00 μm, 5.00 μm, 1.25 μm or any other suitable size can be achieved by selecting objective lenses of varying magnification. The DLP is configured to provide multi-wavelength illumination achieved through a dual-LED illumination design (e.g., 365 nm, 385 nm, 405 nm, 460 nm, 532 nm). In some embodiments, visual monitoring can be achieved, for example, by CCD or CMOS camera, for real-time imaging of the sample and/or to allow for in-registry alignment to existing structures for a variety of patterning applications.

In some embodiments, grayscale patterning can be applied to enable precise, arbitrary printing of image profiles containing a variety of feature shapes and/or sizes over the surface of the substrate. Similar principles used to create the intensity calibration for each DLP can be applied in combination with image superposition to print fine features at high-resolution. Such features may otherwise be unachievable by stitching square pixels together. Grayscale patterning includes the ability to adjust the duty cycle of each individual pixel of the DMD chipset. Such adjustment can be performed simultaneously by uploading a grayscale image.

For example, the grayscale image can encode the duty cycle for each DMD pixel that defines the image directly to the DMD (anywhere between 0%-100%). Initially, an image of the desired printed features can be received, e.g., uploaded. The single grayscale image can be broken down into multiple grayscale images (e.g., multiple bit planes as 1-bit images), calibrated to achieve the final printed result. Breaking down the image into a series of grayscale images (bit planes) can allow fine control of the exposure dose at the substrate surface on a pixel-by-pixel basis, enabling fine control over feature growth as each bit plane is projected onto the substrate surface. Finally, the bit planes are projected in series onto the substrate, building up the print image-by-image to achieve the final desired print.

In the illustrative embodiment, high-resolution XYZ translation stages can adjust the DLP position relative to the sample for focusing projections onto a sample and/or stitching multiple sub-cm² projection areas together to rapidly pattern multi-projection patterns. In the illustrative embodiment, the relative XY movements occurs by movement of the sample stage, while Z movements occur by movement of the DLP itself, although in some embodiments, movement in any of X, Y, Z dimensions can occur in either or both of sample stage or DLP. Customizable calibration can allow fully arbitrary movements of OEM components, to enable surface patterning to take place on various sample types, for example, on standard microscope slides, 4″ silicon wafers, 6″ silicon wafers, and/or on custom sizes of greater or lesser magnitude, limited only by the maximum travel distance of the configured translation stages. Furthermore, an integrated autofocusing technique can be applied with the OEM hardware for seamless ‘stitching’ of multiple projections with high-precision, enabling repeatable high-precision photopatterning.

In the illustrative embodiment, autofocusing can include uploading a periodic pattern of squares to the DMD (e.g., 48 squares×27 squares, with each square being 20 pixels×20 pixels, spaced 20 pixels apart, for the 1920×1080 DMD), and, for example, projecting this pattern onto the center of the sample, roughly within focus, and the camera can capture the image at the surface. A Fast Fourier Transform (FFT) can be performed on the image to decompose the periodic square pattern in spatial co-ordinates into elements of spatial frequency. The FFT thus converts the image from planar ‘x and y’ co-ordinates to ‘1/x and 1/y’ frequency amplitude. When the pattern of squares is in desired/high focus, such that the pattern indicates its highest contrast, the FFT image data illustrates a high amplitude signal at the spatial frequency defined by the period between each square (e.g., 1/40 pixels⁻¹). When outside of desired/high focus, the FFT image data illustrates diminished amplitude and/or shift to lower spatial frequencies.

The FFT image data can be combined in feedback with the Z-axis motorized stage. The focal plane of the DLP can be adjusted into high focus on the sample surface. In some embodiments, auto-focusing can include optimizing the DLP Z-axis position relative to the maximum intensity of the square pattern, coordinating LED exposure of the sample with the camera (i.e., calculating the distance of the sample from the focus by measuring the amount of time it takes for light to propagate from the sample to the camera), and/or maximizing contrast at the edges of the projected squares. In some embodiments, auto-focusing may apply a laser to achieve precise determination of the time for light to reflect from the sample to the camera, through-the-lens secondary image registration (TTL SIR) (where two images of the DMD image overlap on the camera, with optimum focus being achieved when both images perfectly overlap), and applying an infrared (IR) light source to triangulate the position of the substrate surface with the camera. Such techniques can be incorporated to further increase precision auto-focusing should experimental and/or practical needs require. A precision motorized rotation stage (<0.001° resolution) can provide the capability to align a sample feature to the translation axes of the system. This stage may be adjusted manually for rough alignment followed by precision adjustment via user input and/or automated alignment program.

The Tip-tilt stage can enable the parallel alignment of the XY plane of the sample to the XY plane of the DLP and maintain focus throughout the patterning area. Tip-tilt stage alignment can combine real-time feedback from the camera/auto-focusing detailed in the previous section with a precision motorized (<0.001° resolution) Tip-Tilt stage.

In the illustrative embodiment, tip-tilt alignment can conduct auto-focusing at the center of the sample surface, resolving the DLP Z-axis position for optimum focus, and the Z-axis position can be recorded. The sample stage can be moved relative to the DLP in the XY plane towards the perimeter of the sample, and the auto-focusing can be repeated, such that a new DLP Z-axis position is recorded when optimum focus is reached concerning the perimeter. This process can be repeated multiple times along the edge of the sample. For example, a total of five data points can be produced: one data point for the center of the sample and four data points, in quadrature, along the sample's perimeter.

The five data points can be evaluated programmatically to determine the relative orientation of the sample plane with that of the DLP focal plane. The motorized Tip-tilt stage can adjust the sample plane to be in better agreement with the DLP focal plane. This process can be iterated until the auto-focusing protocol produces five equal Z-axis data points, thereby validating that both planes are in agreement over the entire sample surface. Coarse adjustments to the plane of the substrate can be applied during initial steps, after which, fine adjustments can be implemented until the preferred orientation is achieved. The Tip-Tilt stage in coordination with the rotation and XYZ stages, can provide six-axis alignment of the sample with respect to the projected image to enable in-registry printing where a user or automated program may fully align a sample feature to the projected image.

In another example, tip-tilt alignment can conduct auto-focusing on the perimeter of the sample surface, resolving the DLP Z-axis position for optimum focus, and the Z-axis position can be recorded. The sample stage can be moved relative to the DLP in the XY plane around the perimeter of the sample, and the auto-focusing can be repeated, such that a new DLP Z-axis position is recorded when optimum focus is reached concerning the perimeter. This process can be repeated multiple times along the edge of the sample. For example, a total of three data points can be produced along the sample's perimeter that define a rectangle on the sample surface.

The three data points can be evaluated programmatically to precisely determine the relative orientation of the sample plane with that of the DLP focal plane. The evaluation produces two new XYZ positions, XYZ₁ and XYZ₂, on the substrate and they can be reached with the XYZ translation stages. The motorized Tip-tilt stage and XYZ translation stages co-ordinate using XYZ₁ and XYZ₂ to adjust the sample plane to be in better agreement with the DLP focal plane. The motorized Tip-tilt stage finely adjusts the sample to be in-plane with the DLP, first, at XYZ₁ and, second, at XYZ₂. This can produce three equal Z-axis data points, thereby validating that both planes are in agreement over the entire sample surface. The Tip-Tilt stage in coordination with the rotation and XYZ stages, can provide six-axis alignment of the sample with respect to the projected image to enable in-registry printing where a user or automated program may fully align a sample feature to the projected image.

In the illustrative embodiment, the sample holder is configured to utilize a vacuum chuck for selectively mounting a sample directly or an enclosed sample chamber that allows control over the fluid (liquid and/or gaseous) environment for in situ photochemical patterning. The vacuum chuck component is configured to hold a variety of sample types, for example, including ⅘-inch Silicon wafers, microscope slides, and/or custom sample sizes. The enclosed sample chamber is configured as a custom component designed for in situ synthesis (i.e., synthesis of oligonucleotide sequences, peptide sequences, etc.), and/or multiplexed surface patterning (i.e., patterning multiple different materials adjacent to one another and/or simultaneously).

Additionally, temperature control of the substrate can be achieved via the use of a thermo-electric heating element placed underneath the selected sample holder or substrate chuck. The thermo-electric heating element can operate in a feedback loop with a controller (e.g., PID), allowing for precise temperature control over the substrate surface.

Within the present disclosure, the system illustratively includes re-alignment capabilities for in-registry printing in which a sample can be re-aligned to the system within a tolerance dictated by the hardware accuracy (e.g., 0.100 μm) after misalignments, such as in being removed and replaced from the system for in-registry patterning. In the illustrative embodiment, the in-plane alignment (tip-tilt and Z axes) can be achieved using the previously-described FFT autofocusing and/or parallel alignment techniques. The system can record the absolute location of the fiducial mark or feature on the sample which defines the origin of the user-accessible coordinate system. In some embodiments, the location of this fiducial marker or feature can be specified manually in which the user accesses the camera feed and inputs X,Y and/or rotation adjustments to the system until an overlay on top of the camera feed (e.g., alignment grid) is aligned with the visual of the sample feature. In some embodiments, this mark alignment may also be done partly or wholly algorithmically, wherein an algorithm processes the camera output, defines the location, and/or defines the rotation offset of the feature automatically.

A sample environment control system can provide the ability to introduce multiple (e.g., 1 or more; including e.g., 1, 2, 10, 100, or any other suitable number of fluids) distinct fluids to the sample. Each fluid may be used for patterning in single-step or multi-step print (i.e., multilayer printing where each subsequent layer can be the same, or different material patterned one at a time). Furthermore, the system can include fluidics functionalities, which may include microfluidics, to enable mixing of multiple (e.g., 10 or more) distinct fluids in customizable combinations (e.g., fluids 1, 2, and 3; fluids 1, 2, and 4, or any other suitable combination).

The sample environment control system can provide the ability to introduce one or more distinct fluids into a sealed chamber, for example, in precise microliter volumes. The one or more fluids can be photopatterned using the DLP system (e.g., UV-exposure) in single-step or multi-step printing (i.e., multilayer printing where each subsequent layer can be the same, or different material patterned one at a time). The system can enable mixing of one or more distinct fluids in arbitrary combinations (e.g., fluids 1 and 2; fluids 1, 2, and 3, or any other possible combination) and arbitrary proportions (e.g., fluids 1 and 2 mixed in a 1:3 ratio, or fluids 1, 2, and 3 mixed in a 1:2:3 ratio, or another possible combination). This mixing can be achieved using a computer-controlled manifold in coordination with flow feedback controllers and/or sensors to enable the arbitrary fluidic control disclosed above.

The sample environment control system can provide the ability to pattern onto arbitrary sized substrates used in the sealed fluidics chamber. Standard microscope glass slides, 1″×1″ glass slides, 2″×2″ glass slides, etc. can be fit into the sealed fluidics chamber for printing while exposed to micro- or milli-liter amounts of single or mixed fluids. Substrates of arbitrary composition (e.g., silicon) aside from glass can also be used for fluidics photo-lithography.

The manifold can be comprised of pressure, peristaltic, and/or syringe pump driven fluidic reservoirs, flow sensors/controllers, and/or selector valves. Control operation can impart coordination to select the fluid(s) to inject. The system can include one or more fluidic chip modules (e.g., micromixer(s) to process the fluids in a modular fashion before injection into the sample chamber (e.g., mixing, reaction, etc.). This fluidics system can be configured to cycle reagents or access products developed in previous patterning steps. Fluidics cycling can be arranged such that unreacted fluid from the sample chamber can be directed to another fluidic chamber, and/or another system for use. This redirection can effectively allow for multiple fluidic chambers or systems to be ‘daisy chained’ together to reduce fluid waste, and/or increasing printing efficiency and/or throughput. The system can include a gaseous control manifold in which a pressurized or pumped set of gases can be selected and/or controlled through computer operated flow regulators and/or valves to satisfy a particular pressure and/or flow rate determined by the user and measured by system inline components. Control operations can permit gases to be introduced and mixed, similarly as disclosed above, via computer-operated flow regulators and/or valves.

For example, the high resolution photolithography system illustratively includes a fluidics system including a computer-controlled air, peristaltic, and/or syringe pump driven manifold in coordination with flow feedback controllers and/or sensors can provide precision control of fluid delivery. The manifold is illustratively comprised of pressure, peristaltic, and/or syringe pump driven fluidic reservoirs, flow sensors/controllers, and/or selector valves to select the fluid(s) to inject. The fluidics system illustratively includes microfluidic chip module(s) to process the fluids in a modular fashion before injection into the sample chamber (e.g., mixing, reaction, etc.). The fluidics system can be configured to cycle reagents or access products developed in previous patterning steps. The fluidics system can enhance chemical compatibility by applying only highly chemically-resistant materials (e.g., PEEK, Teflon, Glass, etc.) and can incorporate small (<1 mm) ID tubing and/or low dead volume components to reduce overall system dead volume. These features can introduce high cycle performance, reliability, versatility, and/or ease of use. The fluidics system can incorporate a gaseous control manifold in which a pressurized or pumped set of gases is selected and controlled through computer-operated flow regulators and/or valves to satisfy a particular pressure and/or flow rate determined by the user and measured by system inline components.

Within the present disclosure, control operations may be included for governing of the stages, DLP, and fluidics, when applicable, to enable fully-automated and wholly or partly user-controlled alignment, pattern design and/or uploading, patterning sequence definition, and/or orchestrated operation of the modules to complete the patterns. A user interface is illustratively composed of a sequence of pages corresponding to the stage involved in setting-up and executing the print. For example, the sequence may follow generally three main pages: (i.e., Define, Align, Print), however additional functionalities may exist within these.

In the Define page, the user can upload a file containing a single image or sequence of images in a standard grayscale format which defines the layer(s) of the print. These layers may be previewed in sequence to provide a clear visual of the image configurations. The user can specifies print parameters programmatically by creating and/or naming layer definitions which are then assigned by the user to the desired print layers. These layer definitions can include parameters such as gas or fluid(s) selection, flow rate(s), LED wavelength, LED exposure, intensity, and/or additional post-processing parameters (e.g. definitions for fluid washing steps, incubation, etc.) for each layer. Layer definitions or entire print configurations may be exported in a standard file format and re-uploaded for use in any subsequent prints. The user interface can incorporate custom scripts which upon upload, can define a print sequence. A user can download a GUI-defined sequence in a script format to save, modify, and/or re-upload for future use. A visual image of the steps and/or associated parameters which define the print sequence can be presented for user validation.

In the Align page, the user can manually align samples with full control of the DLP and all motorized stages in the system, using the DLP's integrated live camera feed as feedback for relative and/or absolute positioning. The user also has access to automated capabilities for auto-focusing, in-plane alignment, and/or in-registry alignment to which the system's coordinate system may be redefined. The interface can integrate with custom user-defined scripts to access raw camera output and/or relevant system metrics, as well as positioning metrics and/or commands to facilitate automated alignment for a specific use case (e.g., sample scanning, sample inspection, alignment to user-defined fiducial markings, etc.). System procedures such as autofocusing, in-plane alignment, and/or in-registry alignment processes may be called and executed as sub-routines.

In the Print page, the user can execute the print. The user can be presented with a visual image of the steps and/or associated parameters involved in the print sequence. While printing, parameters involved in the print sequence and/or a preview of the current image being patterned as well as any live metrics such as flow rates can be displayed. The user may pause the print in which all processes remain idle until the user resumes the print. The user can stop the print, which, in some embodiments, will cause the stages to return to a default position, any fluids or pressurized gas in a sample chamber to be purged, and/or the system can be returned to its initial state.

Application spaces include but are not limited to microfabricating microfluidics devices, other fluidics devices, sensors, and/or wearable electronic devices, microelectronics, microlenses, metamaterials, microrobotics, microarray fabrication (e.g., DNA, peptides, carbohydrates) via photopatterning and/or in situ photosynthesis, and/or tissue engineering. Compatible materials include but are not limited to commercial photoresists, hydrogels, biomolecules, polymers, and/or any other suitable photoresponsive materials.

Referring to FIG. 4, the fluidics system illustratively includes capacity for up to 10 fluid reservoirs 28 (some reservoir openings illustratively available with associated tubing). Each reservoir 28 can be maintained at desired pressure via a pressure regulator 30, illustratively from the same priming pressure of 2 bar from the same pressure source. A waste reservoir 32 can be available for waste materials/fluids. Fluid valves 34, illustratively three, can provide flow of up to three fluids. A pressure manifold 36 can enable independent pressurization of each reservoir 28 from the pressure source. A mixer 38 can receive two or more fluids from the valves 34 and mix the fluids together upstream of dispatch to the sealed sample chamber 38 of the mounting stage.

Referring to FIG. 5, the high resolution photolithography system is shown with integrated fluidics including an objective lens for the Digital Light Projection (DLP) system 14, which focuses the DMD projection onto the substrate; the mounting stage 18 for the substrate, embodied here with the fluidics environment sample holder 38 (fluidic inlet and outlet lines are shown); the positioning system 20 (X- and Y-Axis) illustratively supporting the mounting stage 18, which moves the DLP projection across the substrate printing surface; and the Tip/Tilt system 21 of the positioning system 20, which adjusts the angular offset between the DLP and the mounting stage 18 (and thus, the substrate printing surface).

Devices, systems, and/or methods within the present disclosure may implement control systems for their disclosed operations. Such control systems may include one or more processors embodied, for example, as microprocessors, memory for storing instructions for execution by the processors, and communications circuitry for conducting various operations according to the processors. Examples of suitable processors may include one or more microprocessors, integrated circuits, system-on-a-chips (SoC), among others. Examples of suitable memory, may include one or more primary storage and/or non-primary storage (e.g., secondary, tertiary, etc. storage); permanent, semi-permanent, and/or temporary storage; and/or memory storage devices including but not limited to hard drives (e.g., magnetic, solid state), optical discs (e.g., CD-ROM, DVD-ROM), RAM (e.g., DRAM, SRAM, DRDRAM), ROM (e.g., PROM, EPROM, EEPROM, Flash EEPROM), volatile, and/or non-volatile memory; among others. Communication circuitry may include components for facilitating processor operations, for example, suitable components may include transmitters, receivers, modulators, demodulators, filters, modems, analog/digital (AD or DA) converters, diodes, switches, operational amplifiers, and/or integrated circuits. AI and/or machine learning implementations may include instructions stored on the memory for execution by the processors for disclosed operations. AI and/or machine learning implementations may be embodied as one or more of neural networks, decision tree learning, regression analysis, Gaussian processes, Bayesian optimization and its associated acquisition functions, including any suitable manner of model, for example but without limitation, supervised, quasi-supervised, and/or unsupervised learning models, such as linear regression, logistic regression, decision tree, SVM, Naive Bayes, kNN, k-means, dimensionality reduction algorithms, gradient boosting algorithms (e.g., GBM, LightGBM, CatBoost) style models, GANs, and transformer models.

Accordingly, the various embodiments of the invention, as disclosed above, are intended to be illustrative, not limiting. Various changes may be made without departing from the spirit and scope of the invention. As a result, it will be apparent for those skilled in the art that the illustrative embodiments described are only examples and that various modifications can be made within the scope of the invention as defined in the appended claims.

1. A high resolution photolithography system, comprising:
a mounting stage for receiving a substrate in position to receive projected light for photolithography;
a light processing system for projecting light onto the mounting stage for photolithography on the substrate;
a positioning system for adjusting relative positioning between the light processing system and the mounting stage; and
a control system for conducting operations for high resolution photolithography, the control system configured to determine relative positioning between the light processing system and the mounting stage and for governing operation of the positioning system for adjusting relative positioning.

2. The high resolution photolithography system of claim 1, wherein the light processing system includes at least one digital light projector (DLP) comprising a Digital Micromirror Device (DMD) chipset comprising a plurality of micromirrors.

3. The high resolution photolithography system of claim 2, wherein the control system is configured to calibrate the DLP for illumination intensity by defining a correction profile corresponding to a duty cycle for each of the plurality of micromirrors.

4. The high resolution photolithography system of claim 3, wherein the control system is configured to define the correction profile by setting the duty cycle at 100% for one of the micromirrors having the lowest native intensity as a reference micromirror, and determining the duty cycle for other ones of the micromirrors by comparison to the reference micromirror.

5. The high resolution photolithography system of claim 4, wherein the control system is configured to support illumination uniformity of within about ±5% of average illumination over at least 95% of an illumination area of the DLP.

6. The high resolution photolithography system of claim 4, wherein the control system encodes the determined duty cycle for each of micromirrors directly onto the DMD chipset.

7. The high resolution photolithography system of claim 4, wherein the control system is configured to define a plurality of grayscale images from a native image, and configured to govern projection of the grayscale images in series from the light processing system onto the mounting stage to build up image-by-image printing of the native image on the substrate.

8. The high resolution photolithography system of claim 2, wherein the control system is configured for conducting autofocusing by governing projection of a predetermined pattern from the light processing system onto the mounting stage for projection on the substrate, capturing an image of the pattern on the substrate having projection thereon, and decomposing the captured image of the pattern into spatial-frequency amplitude.

9. The high resolution photolithography system of claim 8, wherein the control system is configured to govern adjustment of a focal plane of the DLP based on the spatial-frequency amplitude of the captured image.

10. The high resolution photolithography system of claim 9, wherein configuration to govern adjustment of the focal plane includes configuration to govern at least one of adjusting a Z-position of the light projection system relative to the mounting stage, coordinating camera exposure of the substrate by time of light propagation, and maximizing contrast at edges of the predetermined pattern.

11. The high resolution photolithography system of claim 2, wherein the control system is configured for conducting tip-tilt adjustment including governing the positioning system for the light processing system relative to the mounting stage to address at least two different portions of the substrate and to adjust a Z-position of the light projection system relative to the mounting stage for each of the at least two different portions of the substrate for autofocusing.

12. The high resolution photolithography system of claim 11, wherein the at least two different portions include at least two different perimeter portions of the substrate.

13. The high resolution photolithography system of claim 11, wherein conducting tilt-tilt adjustment includes governing the positioning system for tip-tilt including rotation of the mounting stage about at least one of X, Y, and Z axes.

14. The high resolution photolithography system of claim 1, further comprising a sample environmental control feedback system for precisely modulating the temperature and humidity of the environment for patterning the substrate.

15. The high resolution photolithography system of claim 1, further comprising a sample environment control system for introduction of one or more fluids for patterning the substrate.

16. The high resolution photolithography system of claim 15, wherein the sample environment control system includes a sealed chamber received by the mounting stage for receiving the substrate and a fluidics system for selective introduction of the one or more fluids into the sealed chamber for patterning the substrate.

17. The high resolution photolithography system of claim 16, wherein the fluidics system includes a number of fluid reservoirs and a fluidic flow control system for controlling injection of the one or more fluids into the sealed chamber, the fluidic control system including one or more fluidic chip modules for processing fluids before injection into the sealed chamber.

18. The high resolution photolithography system of claim 17, wherein at least one of the one or more fluidic chip modules is a microfluidic chip module.

19. The high resolution photolithography system of claim 17, wherein the control system is configured to govern operation of the one or more fluidic chip modules for multi-step printing.

20. The high resolution photolithography system of claim 19, wherein at least one of the one or more fluidic chip modules is a microfluidic chip module.

21. The high resolution photolithography system of claim 17, wherein the fluidics system includes a mixing chamber for mixing two of more fluids according to governing by the control system.

22. A method of high resolution photolithography, comprising:
defining one or more images for printing via a light processing system onto at least one sample substrate;
aligning the light processing system with the at least one sample substrate received on a mounting stage, wherein aligning includes determining, via a control system, relative positioning between the light processing system and the mounting stage and governing operation of the positioning system for adjusting relative positioning; and
printing the one or more images by projecting light onto the substrate from the light processing system.

23. The method of high resolution photolithography of claim 22, wherein aligning includes autofocusing by projection of a predetermined pattern from the light processing system onto the mounting stage for projection on the sample substrate, capture of an image of the pattern on the substrate having projection thereon, decomposition the captured image of the pattern into spatial-frequency amplitude, and adjustment of a focal plane of a DLP of the light processing system, via the control system, based on the spatial-frequency amplitude of the captured image.

24. The method of high resolution photolithography of claim 23, wherein aligning includes tip-tilt adjustment comprising addressing at least two different portions of the sample substrate and adjusting a Z-position of the light projection system relative to the mounting stage with respect to each of the at least two different portions of the substrate for autofocusing.

25. The method of high resolution photolithography of claim 24, wherein the at least two different portions include at least two different perimeter portions of the substrate.

26. The method of high resolution photolithography of claim 22, wherein printing includes injecting one or more fluids into a sealed chamber of the mounting stage, via a fluidics system.

27. The method of high resolution photolithography of claim 22, wherein printing includes printing high-resolution, wide-area, high-fidelity DNA microarrays onto arbitrarily sized glass substrates, via injection of fluids into the sealed fluidic chamber in coordination with DLP projection.

28. The method of high resolution photolithography of claim 27, wherein printing is conducted subsequent to tip-tilt adjustment and auto-focusing.

29. The method of high resolution photolithography of claim 22, wherein printing includes microfabricating microfluidics devices, other fluidics devices, sensors, wearable electronic devices, microelectronics, microlenses, metamaterials, microrobotics, microarray fabrication via photopatterning and/or in-situ photosynthesis, and/or tissue engineering.

30. The method of high resolution photolithography of claim 29, wherein compatible materials include but are not limited to commercial photoresists, hydrogels, biomolecules, polymers, and/or any other suitable photoresponsive materials.
